(19) United States
(12) Patent Application Publication
(10) Pub. No.: US 2026/0080136 A1
(43) Pub. Date: Mar. 19, 2026

(54) EFFICIENT POWER MODELING OF MULTI-DOMAIN CLOCK GATING CIRCUITS

(71) Applicant: International Business Machines Corporation, Armonk, NY (US)

(72) Inventors: Spandana V Rachamalla, Bengaluru (IN); Nagashyamala R. Dhanwada, Tenafly, NJ (US); William W. Dungan, Wappingers Falls, NY (US)

(21) Appl. No.: 18/884,255

(22) Filed: Sep. 13, 2024

(51) Int. Cl. G06F 30/32

(52) U.S. Cl. CPC G06F 30/32

(57) ABSTRACT

Embodiments of the disclosure include a method for estimating the power consumption of a micro gated clocking local clock buffer circuit. The method involves obtaining a model of the circuit with a global enable input and multiple local clock enable inputs. It includes performing three simulations: a first simulation with the global enable off to determine global clock capacitance, a second simulation with the global enable on and local enables off to determine global enable capacitance, and a third simulation with the global enable on and local enables active to determine local clock capacitances. The power consumption is then calculated based on the global clock capacitance, the global enable capacitance, and the local clock capacitance for each of the local clock enable inputs.

### BACKGROUND

Power consumption in integrated circuits has become an increasingly important consideration in modern electronic device design. As the demand for more powerful and energy-efficient devices continues to grow, designers may face challenges in accurately modeling and analyzing power consumption, particularly in complex circuits with multiple clock domains.

Traditional clock gating techniques may be used to reduce power consumption by selectively disabling portions of a circuit when they are not in use. However, these techniques may have limitations when applied to circuits with numerous small domains. In such cases, using standard Local Clock Buffers (LCBs) for each domain may result in a large number of underloaded LCBs, potentially leading to inefficient power usage.

To address this issue, multi-domain clock gating circuits, such as Micro Gated Clocking (MGC), may be implemented. These circuits may allow a single LCB to drive multiple domains, with additional enable signals for separate control of each domain. While this approach may offer potential power savings, it may also introduce new challenges in power modeling and analysis.

### SUMMARY

Embodiments of the disclosure include a method for estimating the power consumption of a micro gated clocking local clock buffer circuit. The method includes obtaining a model of the micro gated clocking local clock buffer circuit, wherein the model includes a global enable input and a plurality of local clock enable inputs and performing a first simulation of an operation of the micro gated clocking local clock buffer circuit with an off signal provided to the global enable input to determine a global clock capacitance for the micro gated clocking local clock buffer circuit. The method also includes performing a second simulation of the operation of the micro gated clocking local clock buffer circuit with an enable signal provided to the global enable input and off signals provided to each of the plurality of local clock enable inputs, wherein the enable signal alternates between an on and off signal, to determine a global enable capacitance parametrized on a duty cycle of the enable signal. The method further includes performing a third simulation of the operation of the micro gated clocking local clock buffer circuit with the enable signal provided to the global enable input and activation signals provided to each of the plurality of local clock enable inputs, wherein each of the activation signals alternates between an on and off signal with a corresponding activity level, to determine a local clock capacitance for each of the plurality of local clock enable inputs. The method also includes calculating the power consumption of the micro gated clocking local clock buffer circuit based on the global clock capacitance, the global enable capacitance, and the local clock capacitance for each of the plurality of local clock enable inputs.

Embodiments of the disclosure include a system having a memory having computer readable instructions and a processing device for executing the computer readable instructions, the computer readable instructions controlling the processing device to perform operations. The operations include obtaining a model of the micro gated clocking local clock buffer circuit, wherein the model includes a global enable input and a plurality of local clock enable inputs and performing a first simulation of an operation of the micro gated clocking local clock buffer circuit with an off signal provided to the global enable input to determine a global clock capacitance for the micro gated clocking local clock buffer circuit. The operations also include performing a second simulation of the operation of the micro gated clocking local clock buffer circuit with an enable signal provided to the global enable input and off signals provided to each of the plurality of local clock enable inputs, wherein the enable signal alternates between an on and off signal, to determine a global enable capacitance parametrized on a duty cycle of the enable signal. The operations further include performing a third simulation of the operation of the micro gated clocking local clock buffer circuit with the enable signal provided to the global enable input and activation signals provided to each of the plurality of local clock enable inputs, wherein each of the activation signals alternates between an on and off signal with a corresponding activity level, to determine a local clock capacitance for each of the plurality of local clock enable inputs. The operations also include calculating the power consumption of the micro gated clocking local clock buffer circuit based on the global clock capacitance, the global enable capacitance, and the local clock capacitance for each of the plurality of local clock enable inputs.

Embodiments of the disclosure also include a computer program product for circuit design optimization. The computer program product has a set of one or more computer-readable storage media and program instructions, collectively stored in the set of one or more storage media, for causing a processor set to perform computer operations. The operations include obtaining a model of the micro gated clocking local clock buffer circuit, wherein the model includes a global enable input and a plurality of local clock enable inputs and performing a first simulation of an operation of the micro gated clocking local clock buffer circuit with an off signal provided to the global enable input to determine a global clock capacitance for the micro gated clocking local clock buffer circuit. The operations also include performing a second simulation of the operation of the micro gated clocking local clock buffer circuit with an enable signal provided to the global enable input and off signals provided to each of the plurality of local clock enable inputs, wherein the enable signal alternates between an on and off signal, to determine a global enable capacitance parametrized on a duty cycle of the enable signal. The operations further include performing a third simulation of the operation of the micro gated clocking local clock buffer circuit with the enable signal provided to the global enable input and activation signals provided to each of the plurality of local clock enable inputs, wherein each of the activation signals alternates between an on and off signal with a corresponding activity level, to determine a local clock capacitance for each of the plurality of local clock enable inputs. The operations also include calculating the power consumption of the micro gated clocking local clock buffer circuit based on the global clock capacitance, the global enable capacitance, and the local clock capacitance for each of the plurality of local clock enable inputs.

The above features and advantages, and other features and advantages, of the disclosure are readily apparent from the following detailed description when taken in connection with the accompanying drawings.

### BRIEF DESCRIPTION OF THE DRAWINGS

FIG. 1 illustrates a computing environment for executing methods related to circuit design optimization in accordance with an exemplary embodiment.

FIG. 2 illustrates a flow diagram of a method for estimating power consumption of a micro gated clocking local clock buffer circuit in accordance with an exemplary embodiment.

FIG. 3 illustrates a block diagram of a micro gated clocking local clock buffer with global and micro enables in accordance with an exemplary embodiment.

FIG. 4 is a schematic of a multi-domain clock gating circuit with multiple enable signals and corresponding output clocks in accordance with an exemplary embodiment.

FIG. 5 is a block diagram of a system to perform circuit design in accordance with an exemplary embodiment.

FIG. 6 is a flow diagram of a method of fabricating an integrated circuit in accordance with an exemplary embodiment.

The above features and advantages, and other features and advantages, of the disclosure are readily apparent from the following detailed description when taken in connection with the accompanying drawings.

### DETAILED DESCRIPTION

Power consumption in integrated circuits has become an increasingly important consideration in modern electronic device design. As the demand for more powerful and energy-efficient devices continues to grow, designers face challenges in accurately modeling and analyzing power consumption, particularly in complex circuits with multiple clock domains. Traditional clock gating techniques are used to reduce power consumption by selectively disabling portions of a circuit when they are not in use. However, these techniques have limitations when applied to circuits with numerous small domains. In such cases, using standard Local Clock Buffers (LCBs) for each domain results in a large number of underloaded LCBs, potentially leading to inefficient power usage.

Existing power modeling approaches for multi-domain clock gating circuits generate current or power models for every mode and corner-load combination, potentially resulting in large, process-voltage-temperature (PVT) dependent, and mode-dependent models. Other approaches use contributors or capacitances for every mode, which leads to medium-sized, PVT-independent, but still mode-dependent models. These existing methods have limitations in terms of accuracy, complexity, and efficiency. Simpler approaches, such as averaging, do not provide a sufficiently accurate representation of power dissipation, making assessment of the true power savings obtained through micro clock gating difficult. Additionally, some methods require a large number of simulations and generate complex models, potentially increasing characterization costs and model sizes. Furthermore, there is a need for micro-domain power granularity to accurately assess power consumption in multi-domain circuits. Existing models do not provide the level of detail required for comprehensive analysis of power distribution across different domains.

Embodiments of the disclosure address the problem of efficiently modeling power consumption in multi-domain clock gating circuits, specifically Micro Gated Clocking (MGC) Local Clock Buffers (LCBs). The method for estimating power consumption of a micro gated clocking local clock buffer circuit involves obtaining a model of the circuit with a global enable input and multiple local clock enable inputs. The method performs three simulations: a first simulation with the global enable off to determine global clock capacitance, a second simulation with the global enable on and local enables off to determine global enable capacitance, and a third simulation with the global enable on and local enables active to determine local clock capacitances. The power consumption is then calculated based on the determined capacitances from the three simulations. This method provides an efficient way to estimate power for micro gated clock circuits by determining capacitance values through targeted simulations.

Embodiments of the disclosure address the problem of efficiently modeling power consumption in multi-domain clock gating circuits, specifically Micro Gated Clocking (MGC) Local Clock Buffers (LCBs). Existing power modeling approaches for multi-domain clock gating circuits generate current or power models for every mode and corner-load combination, potentially resulting in large, process-voltage-temperature (PVT) dependent, and mode-dependent models. Other approaches may use contributors or capacitances for every mode, which may lead to medium-sized, PVT-independent, but still mode-dependent models.

These existing methods may have limitations in terms of accuracy, complexity, and efficiency. Simpler approaches, such as averaging, may not provide a sufficiently accurate representation of power dissipation, making it difficult to assess the true power savings obtained through micro clock gating. Additionally, some methods may require a large number of simulations and generate complex models, potentially increasing characterization costs and model sizes. Furthermore, there may be a need for micro-domain power granularity to accurately assess power consumption in multi-domain circuits. Existing models may not always provide the level of detail required for comprehensive analysis of power distribution across different domains.

As integrated circuit designs become more complex and power-sensitive, there may be a growing need for improved methods of power modeling and analysis, particularly for multi-domain clock gating circuits. Addressing these challenges may enable more accurate power estimation, facilitate better assessment of power savings, and ultimately lead to more energy-efficient electronic devices.

Embodiments of the disclosure include methods for estimating the power consumption of a micro gated clocking local clock buffer circuit by obtaining a model of the circuit that includes a global enable input and multiple local clock enable inputs. The method involves performing three simulations: the first with the global enable off to determine the global clock capacitance, the second with the global enable on and local enables off to determine the global enable capacitance, and the third with the global enable on and local enables active to determine the local clock capacitances. In exemplary embodiments, performing a first simulation with the global enable input off to determine the global clock capacitance isolates the power consumption due to the global clock signal alone ensures that the baseline power consumption of the global clock is accurately captured without interference from local clock activities. Conducting a second simulation with the global enable input on and local clock enable inputs off, where the global enable signal alternates with a specific duty cycle, allows for the determination of the global enable capacitance. This approach captures the dynamic behavior of the global enable signal, providing a more precise measurement of its contribution to overall power consumption. Executing a third simulation with the global enable input on and activation signals provided to each of the local clock enable inputs, where each activation signal alternates with a corresponding activity level, enables the determination of local clock capacitances. This step ensures that the power contributions of each local clock domain are accurately measured, reflecting their individual activity levels. The power consumption of the micro gated clocking local clock buffer circuit is then calculated based on the global clock capacitance, the global enable capacitance, and the local clock capacitances for each local clock enable input, providing a detailed and accurate estimation of the circuit's power usage. Accordingly, the method accounts for both global and local clock gating effects, leading to a more precise power model that can be used for optimization and analysis. Overall, this method reduces the complexity and number of simulations required for accurate power modeling, making it more efficient while maintaining high accuracy. This approach addresses the challenges of power estimation in multi-domain clock gating circuits, providing a practical solution for designers to optimize power consumption in integrated circuits.

Descriptions of various embodiments of the present disclosure are presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

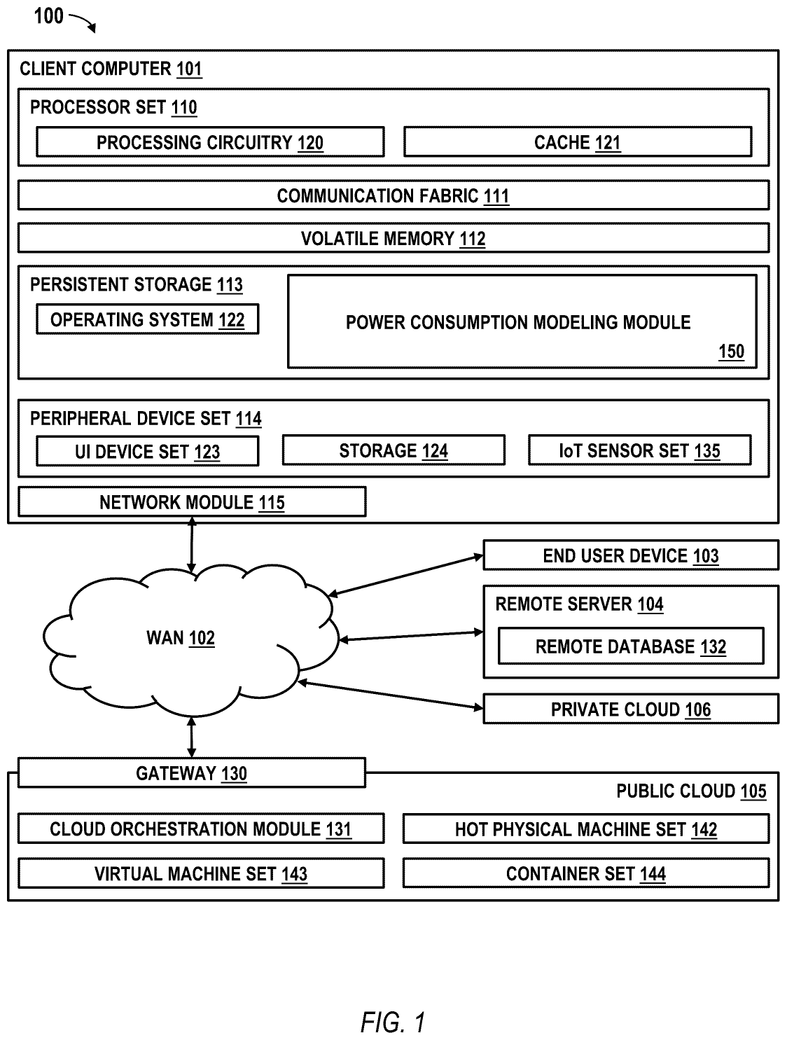

FIG. 1 illustrates a computing environment 100, according to an embodiment. Computing environment 100 contains an example of an environment for the execution of at least some of the computer code involved in performing the inventive methods, such as a power consumption modeling module 150 for performing circuit design optimization. In addition to the power consumption modeling module 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and power consumption modeling module 150, as identified above), peripheral device set 114 (including user interface (UI) device set 123, storage 124, and Internet of Things (IOT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in power consumption modeling module 150 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface-type operating systems that employ a kernel. The code included in the power consumption modeling module 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

According to one or more embodiments, the computing environment 100 can provide for remote data storage. For example, the computer 101 can be a cloud storage system or other suitable system for storing data that is accessible to a user remotely, such as by accessing the computer 101 using the end user device 103. That is, a user can send a user operation (also referred to as a “user request”) from the end user device 103 to the computer 101 via the WAN 102. Although the user operation may appear to be simple, such as uploading an object to a cloud storage system, the complications of operating a cloud computing system often have side effects and produce ancillary data, which may be consumed by both the operator of the system (e.g., the computer 101) and by users or other components of the cloud architecture (e.g., the computing environment 100). Ancillary data may be created by user operations that trigger the creation of the ancillary data. Ancillary data may be resource consumption information, notification data, and/or the like, including combinations and/or multiples thereof. Data for an independent event may be inferred from another event (e.g., event to update resource consumption information for an entity in a system also means that the total consumption information for the oner of the entity is also updated).

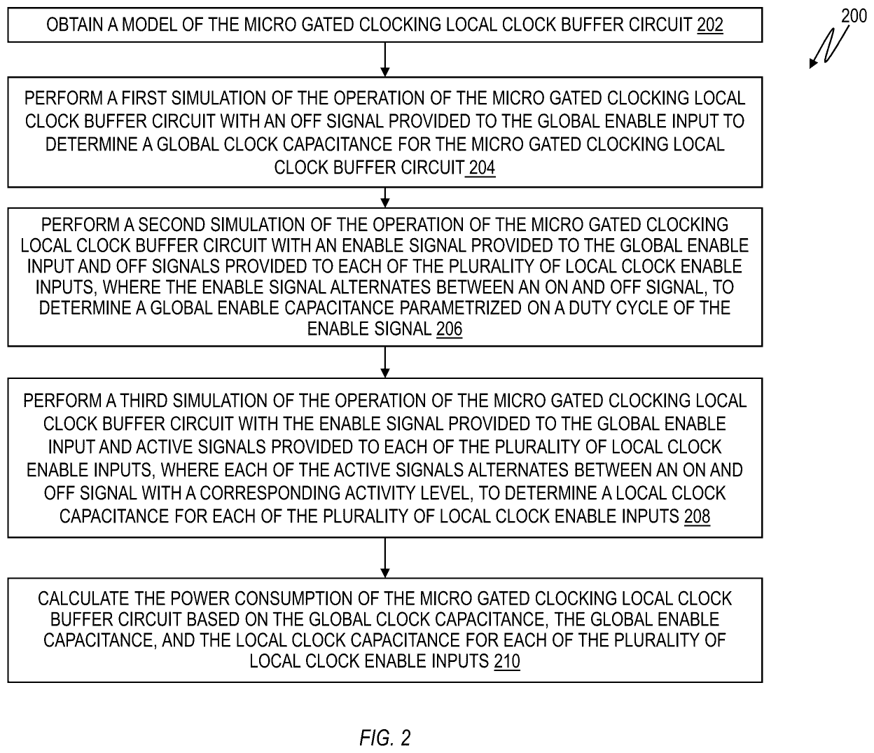

Referring now to FIG. 2, a flow diagram of a method 200 for estimating power consumption of a micro gated clocking local clock buffer circuit in accordance with an exemplary embodiment is shown. In exemplary embodiments, the method 200 is performed by the power consumption modeling module of the computing environment 100 shown in FIG. 1. The power consumption modeling module may be part of an electronic design application (EDA) that is used to design and test integrated circuits. The method 200 begins at block 202 by obtaining a model of the micro gated clocking local clock buffer circuit. In exemplary embodiments, the model includes a global enable input, a plurality of local clock enable inputs, and all other relevant control signals, such that the model is able to represent all of the circuit's operational states.

Next, as shown at block 204, the method 200 includes performing a first simulation of the operation of the micro gated clocking local clock buffer circuit with an off signal provided to the global enable input to determine a global clock capacitance for the micro gated clocking local clock buffer circuit. This step isolates the power consumption due to the global clock signal alone, ensuring that the baseline power consumption of the global clock is accurately captured without interference from local clock activities.

The method then proceeds to block 206 and includes performing a second simulation of the operation of the micro gated clocking local clock buffer circuit with an enable signal provided to the global enable input and off signals provided to each of the plurality of local clock enable inputs, where the enable signal alternates between an on and off signal, to determine a global enable capacitance parametrized on a duty cycle of the enable signal. This step captures the dynamic behavior of the global enable signal, providing a more precise measurement of the global enable signal's contribution to overall power consumption.

Next, as shown at block 208, the method 200 includes performing a third simulation of the operation of the micro gated clocking local clock buffer circuit with the enable signal provided to the global enable input and activation signals provided to each of the plurality of local clock enable inputs, where each of the activation signals alternates between an on and off signal with a corresponding activity level, to determine a local clock capacitance for each of the plurality of local clock enable inputs 208. During the third simulation, the state of each activation signal is varied, and the corresponding activity level is recorded. The activity level of each activation signal is essentially the duty cycle of the activation signal, which represents the proportion of time the signal is in the ‘on’ state compared to the total simulation time. By alternating the activation signals and recording their duty cycles, the simulation accurately captures the dynamic behavior and switching activity of each local clock domain. In exemplary embodiments, the activation signals provided to the plurality of local clock enable inputs are different such that all of various combinations of each of the local clock enable inputs being active and/or inactive are covered during the third simulation. The third simulation is configured to ensure that the power contributions of each local clock domain are accurately measured, reflecting their individual activity levels. The recorded activity levels are then used in the final calculation of the power consumption of the micro gated clocking local clock buffer circuit, providing a detailed and accurate estimation of the circuit's power usage. This step ensures that the power contributions of each local clock domain are accurately measured, reflecting their individual activity levels.

The method 200 concludes at block 210 by calculating the power consumption of the micro gated clocking local clock buffer circuit based on the global clock capacitance, the global enable capacitance, and the local clock capacitance for each of the plurality of local clock enable inputs 210. The power consumption is calculated by multiplying the sum of the global clock capacitance, the global enable capacitance times the duty cycle, and the clock capacitance for each of the plurality of local clock enable inputs times the corresponding activity level by a square of the voltage level and frequency of a global clock signal. In one embodiment, the power consumption is calculated using the following formula,

$$Power consumption = {V}^{2} * F * ( GCKNcap + Ecap * Edc + {\sum }_{n = 1}^{N} LCKncap * LCKnact ) ,$$

where V is the voltage of the global clock signal, F is the frequency of the global clock signal, GCKNcap is the global clock capacitance determined by the first simulation, Ecap is the a global enable capacitance determined by the second simulation, Edc is the duty cycle of the global enable signal, LCKncap is the local clock capacitance for the n^{th} micro gated clock, and LCKnact is the activity level, or duty cycle, for the n^{th} enable signal during the third simulation. This calculation provides a detailed and accurate estimation of the circuit's power usage, accounting for both global and local clock gating effects, leading to a more precise power model that can be used for optimization and analysis. In exemplary embodiments, the method 200 ensures that the model of the micro gated clocking local clock buffer circuit is independent of process, voltage, and temperature (PVT) variations, enhancing the robustness and reliability of the power estimation.

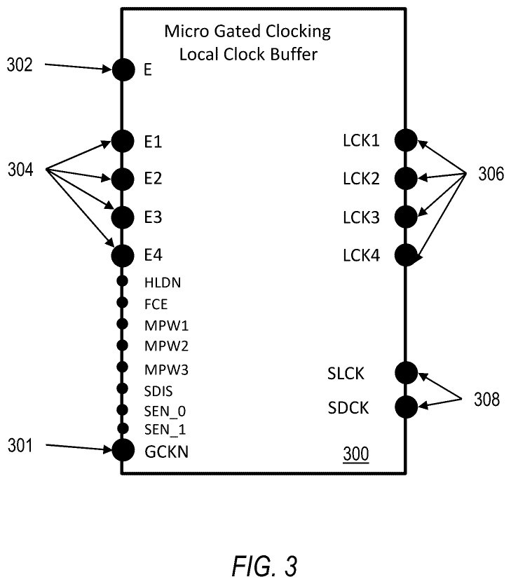

Referring now to FIG. 3, a block diagram of a micro gated clocking local clock buffer 300 with global and micro enables in accordance with an exemplary embodiment is shown. The micro gated clocking local clock buffer 300 includes a global enable input 302, micro enables input 304, functional outputs 306, scan outputs 308, and a global clock signal input 301. The micro gated clocking local clock buffer 300 is designed to manage clock signals within a circuit. The micro gated clocking local clock buffer 300 receives the global enable signal input 302, which controls the overall enabling of the clock signals. The global enable signal input 302 allows the micro gated clocking local clock buffer 300 to activate or deactivate the clock signals based on the input it receives.

The micro enables input 304 provides individual control over multiple clock domains within the micro gated clocking local clock buffer 300. Each input in the micro enables input 304 corresponds to a specific clock domain, allowing for selective enabling or disabling of these domains. This feature enables fine-grained control over the clock signals, optimizing power consumption by deactivating unused domains. The functional outputs 306 are the primary clock outputs of the micro gated clocking local clock buffer 300. These outputs deliver the clock signals to various functional units within the circuit. Each output in the functional outputs 306 corresponds to a specific clock domain controlled by the micro enables input 304. The scan outputs 308 are used for testing and diagnostic purposes. These outputs provide clock signals to scan chains within the circuit, enabling the verification of the circuit's functionality and the detection of faults. The scan outputs 308 ensure that the circuit operates correctly under various conditions.

The global clock signal input 301 is the main clock signal input to the micro gated clocking local clock buffer 300. The global clock signal input 301 provides the base clock signal that is distributed and managed by the micro gated clocking local clock buffer 300. The micro gated clocking local clock buffer 300 uses the global clock signal input 301 in conjunction with the global enable signal 302 and micro enables input 304 to generate the appropriate clock signals for the functional outputs 306 and scan outputs 308.

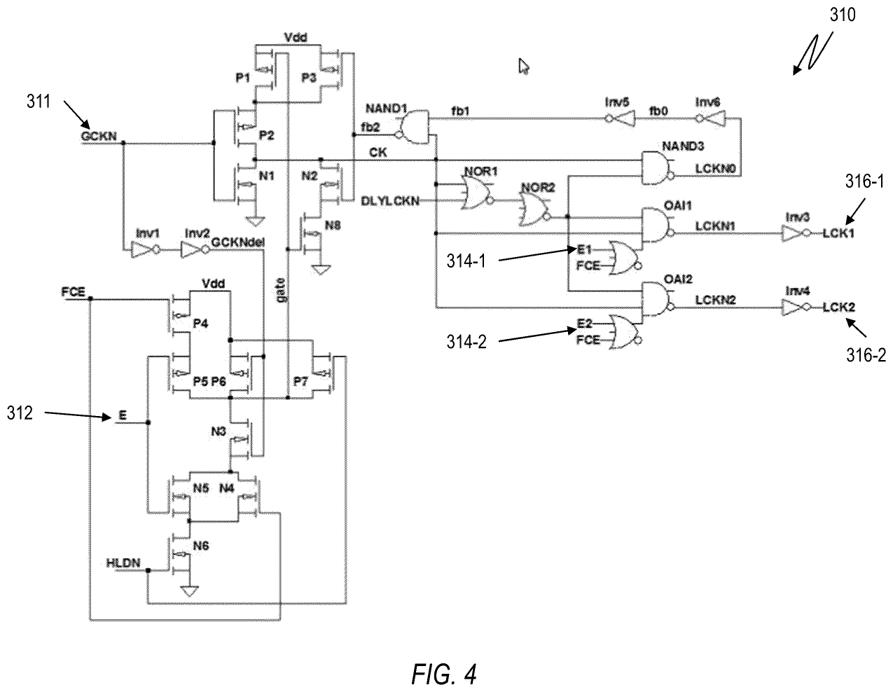

Referring now to FIG. 4, a schematic of a multi-domain clock gating circuit 310 with multiple enable signals and corresponding output clocks in accordance with an exemplary embodiment is shown. The circuit 310 includes a global clock signal 311, a global enable signal 312, a first micro enable signal 314-1, a second micro enable signal 314-2, a first clock output signal 316-1, and a second clock output signal 316-2. The global clock signal 311 provides the base clock signal for the circuit 310. The global clock signal 311 is distributed and managed within the circuit 310 to generate the appropriate clock signals for various components. The global enable signal 312 controls the overall enabling of the clock signals within the circuit 310. The global enable signal 312 allows the circuit 310 to activate or deactivate the clock signals based on the input it receives.

The first micro enable signal 314-1 provides individual control over a specific clock domain within the circuit 310. The first micro enable signal 314-1 allows for selective enabling or disabling of this domain, optimizing power consumption by deactivating unused domains. The second micro enable signal 314-2 provides individual control over another specific clock domain within the circuit 310. The second micro enable signal 314-2 allows for selective enabling or disabling of this domain, further optimizing power consumption by deactivating unused domains. The first clock output signal 316-1 is the primary clock output for the clock domain controlled by the first micro enable signal 314-1. The first clock output signal 316-1 delivers the clock signal to various functional units within the circuit 310. The second clock output signal 316-2 is the primary clock output for the clock domain controlled by the second micro enable signal 314-2. The second clock output signal 316-2 delivers the clock signal to various functional units within the circuit 310.

This invention improves the functioning of a computer by providing a more efficient and accurate method for estimating power consumption in multi-domain clock gating circuits, specifically Micro Gated Clocking Local Clock Buffers (LCBs). Traditional methods for power modeling in such circuits often result in large, process-voltage-temperature (PVT) dependent, and mode-dependent models, which can be complex and inefficient. These traditional methods may also require a large number of simulations, increasing characterization costs and model sizes.

By introducing a method that involves obtaining a model of the circuit with a global enable input and multiple local clock enable inputs, and performing targeted simulations to determine various capacitances, this invention significantly reduces the complexity and number of simulations required to accurately determine a power consumption of a micro gated clocking local clock buffer. The method includes performing three specific simulations: one with the global enable off to determine global clock capacitance, one with the global enable on and local enables off to determine global enable capacitance, and one with the global enable on and local enables active to determine local clock capacitances. This targeted approach ensures that the power contributions of each clock domain are accurately measured, reflecting their individual activity levels.

The power consumption is then calculated based on the determined capacitances, providing a detailed and accurate estimation of the circuit's power usage. This method accounts for both global and local clock gating effects, leading to a more precise power model that can be used for optimization and analysis. As a result, the invention enables more accurate power estimation, facilitates better assessment of power savings, and ultimately leads to more energy-efficient electronic devices.

Previously, the power consumption of local clock buffers was performed using traditional clock gating techniques and existing power modeling approaches. These methods often involved generating current or power models for every mode and corner-load combination, which could result in large, process-voltage-temperature (PVT) dependent, and mode-dependent models. This approach required extensive simulations to cover all possible operational states, leading to increased characterization costs and larger model sizes.

In traditional methods, each local clock buffer would be modeled individually, with power consumption estimated based on the switching activity of the clock signals and the enable signals. For circuits with numerous small domains, this meant using standard local clock buffers for each domain, resulting in a large number of underloaded local clock buffers. This could lead to inefficient power usage, as the power savings from clock gating were not fully realized due to the overhead of managing multiple local clock buffers.

Simulations were typically performed for each mode of operation, where the global enable signal and local enable signals were toggled in various combinations to observe the power consumption. This process was repeated for different corner-load combinations, further increasing the number of required simulations. The power consumption was then calculated based on the switching activity and capacitance values obtained from these simulations. For example, for an local clock buffer with four functional outputs, such as the one shown in FIG. 3, seventeen separate simulations were required to observe the power consumption in each possible configuration.

Additionally, simpler approaches such as averaging were sometimes used to estimate power consumption. However, these methods did not provide a sufficiently accurate representation of power dissipation, making it difficult to assess the true power savings obtained through clock gating. The lack of micro-domain power granularity in these models also limited their ability to accurately analyze power distribution across different domains within the circuit. Overall, the traditional methods for estimating the power consumption of local clock buffers were complex, time-consuming, and often resulted in large, inefficient models that did not fully capture the potential power savings from clock gating in multi-domain circuits.

In exemplary embodiments, the disclosed method for local clock buffer power modeling allows computer systems to optimize the power consumption of integrated circuits more effectively. By accurately modeling and analyzing power usage in multi-domain clock gating circuits, designers can make informed decisions to reduce power consumption, extend battery life in portable devices, and improve overall system performance. This leads to electronic devices that are not only more energy-efficient but also more reliable and capable of handling complex tasks with reduced thermal and power-related issues.

In exemplary embodiments, an efficient and accurate method for estimating power consumption in multi-domain clock gating circuits, specifically Micro Gated Clocking Local Clock Buffers (LCBs), while ensuring that the method is independent of process, voltage, and temperature (PVT) variations is provided. The method involves obtaining a model of the circuit with a global enable input and multiple local clock enable inputs, and performing targeted simulations to determine various capacitances. The method includes performing three specific simulations: one with the global enable off to determine global clock capacitance, one with the global enable on and local enables off to determine global enable capacitance, and one with the global enable on and local enables active to determine local clock capacitances. This targeted approach ensures that the power contributions of each clock domain are accurately measured, reflecting their individual activity levels. In exemplary embodiments, the power consumption is calculated based on the determined capacitances to provide a detailed and accurate estimation of the circuit's power usage. This method accounts for both global and local clock gating effects, leading to a more precise power model that can be used for optimization and analysis. By being PVT independent, the method enhances the robustness and reliability of the power estimation. As a result, the method provides a more accurate power estimation, facilitates better assessment of power savings, and ultimately leads to more energy-efficient electronic devices.

In one embodiment, the method for estimating power consumption of a micro gated clocking local clock buffer circuit, focusing on the process of obtaining the model of the circuit. This embodiment begins with loading a design of micro clock gating circuits within the micro gated clocking local clock buffer circuit. The design includes all relevant control signals, such as the global enable input and multiple local clock enable inputs, ensuring that the model can represent all operational states of the circuit. By incorporating these elements, the model provides a comprehensive basis for accurate power estimation.

Once the design is loaded, the next step involves loading a power model for each of the micro clock gated circuits. This power model includes detailed information about the capacitances and switching activities associated with each circuit. Additionally, a simulation file representing a workload for which the power consumption estimation is being performed is loaded. This simulation file contains data on the expected operational conditions and activities of the circuit under various scenarios. The method then extracts activities for the micro clock gating circuits from the simulation file, capturing the dynamic behavior and switching activity of each local clock domain. Finally, the power for the design, including the micro clock gating circuit, is computed using the capacitances and the extracted activities. This approach ensures that the model accurately reflects the operational characteristics and workload of the circuit, leading to a precise estimation of power consumption.

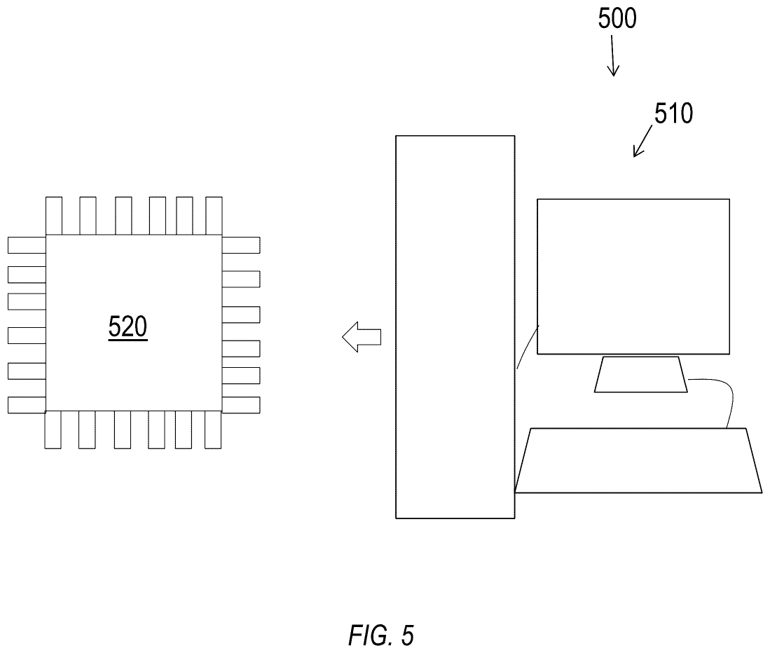

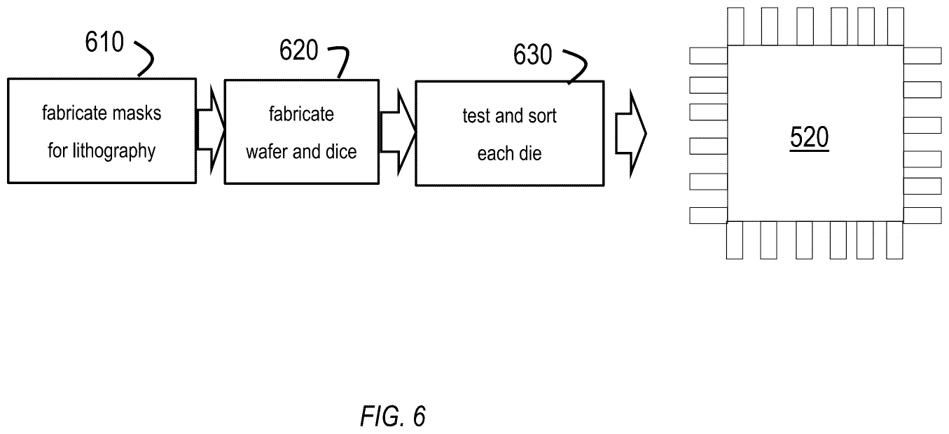

Referring now to FIG. 5, a block diagram of a system 500 to perform circuit design optimization according to one or more embodiments. The system 500 includes processing circuitry 510 used to generate the circuit design that is ultimately fabricated into an integrated circuit 520. The steps involved in the fabrication of the integrated circuit 520 are well-known and briefly described herein. Once the physical layout is finalized, based, in part, on the circuit design optimization according to one or more embodiments, the finalized physical layout is provided to a foundry. Masks are generated for each layer of the integrated circuit based on the finalized physical layout. Then, the wafer is processed in the sequence of the mask order. The processing includes photolithography and etch. This is further discussed with reference to FIG. 6.

Particularly, FIG. 6 is a flow diagram of a method 600 of fabricating an integrated circuit according to one or more embodiments. Once the physical design data is obtained, based, in part, on performing circuit design optimization as described herein, the integrated circuit 520 can be fabricated according to known processes that are generally described with reference to FIG. 6. Generally, a wafer with multiple copies of the final design is fabricated and cut (i.e., diced) such that each die is one copy of the integrated circuit 520. At block 610, the processes include fabricating masks for lithography based on the finalized physical layout. At block 620, fabricating the wafer includes using the masks to perform photolithography and etching. Once the wafer is diced, testing and sorting each die is performed, at block 630, to filter out any faulty die.

While the foregoing is directed to embodiments of the present disclosure, other and further embodiments of the present disclosure may be devised without departing from the basic scope thereof, and the scope thereof is determined by the claims that follow.

What is claimed is:

1. A method for estimating a power consumption of a micro gated clocking local clock buffer circuit, the method comprising:
obtaining a model of the micro gated clocking local clock buffer circuit, wherein the model includes a global enable input and a plurality of local clock enable inputs;
performing a first simulation of an operation of the micro gated clocking local clock buffer circuit with an off signal provided to the global enable input to determine a global clock capacitance for the micro gated clocking local clock buffer circuit;
performing a second simulation of the operation of the micro gated clocking local clock buffer circuit with an enable signal provided to the global enable input and off signals provided to each of the plurality of local clock enable inputs, wherein the enable signal alternates between an on and off signal, to determine a global enable capacitance parametrized on a duty cycle of the enable signal;
performing a third simulation of the operation of the micro gated clocking local clock buffer circuit with the enable signal provided to the global enable input and activation signals provided to each of the plurality of local clock enable inputs, wherein each of the activation signals alternates between an on and off signal with a corresponding activity level, to determine a local clock capacitance for each of the plurality of local clock enable inputs; and
calculating the power consumption of the micro gated clocking local clock buffer circuit based on the global clock capacitance, the global enable capacitance, and the local clock capacitance for each of the plurality of local clock enable inputs.

2. The method of claim 1, wherein the model of the micro gated clocking local clock buffer circuit is obtained by:
loading a design of micro clock gating circuits in the micro gated clocking local clock buffer circuit;
loading a power model for each of the micro clock gated circuits;
loading a simulation file representing a workload for which a power consumption estimation is being performed;
extracting activities for the micro clock gating circuits from simulation file; and
computing the power for the design including the micro clock gating circuit by using the capacitances and the extracted activities.

3. The method of claim 1, wherein the power consumption of the micro gated clocking local clock buffer circuit is calculated by multiplying a sum of the global clock capacitance, the global enable capacitance times the duty cycle, and the clock capacitance for each of the plurality of local clock enable inputs times the corresponding activity level by a square of a voltage level and frequency of a global clock signal.

4. The method of claim 1, wherein plurality of local clock enable inputs is at least two.

5. The method of claim 1, wherein the third simulation includes varying a state of each of the activation signals and recording the corresponding activity level.

6. The method of claim 5, wherein the corresponding activity level of each of the activation signals is a duty cycle of the activation signals.

7. The method of claim 1, wherein the model of the micro gated clocking local clock buffer circuit is independent of process, voltage, and temperature (PVT) variations in the micro gated clocking local clock buffer circuit.

8. The method of claim 1, wherein the micro gated clocking local clock buffer circuit comprises a plurality of local clock outputs, each corresponding to one of the plurality of local clock enable inputs.

9. The method of claim 1, wherein performing the first, second, and third simulations capture all operational states of the micro gated clocking local clock buffer circuit.

10. A system comprising:
a memory comprising computer readable instructions; and
a processing device for executing the computer readable instructions, the computer readable instructions controlling the processing device to perform operations comprising:
obtaining a model of a micro gated clocking local clock buffer circuit, wherein the model includes a global enable input and a plurality of local clock enable inputs;
performing a first simulation of an operation of the micro gated clocking local clock buffer circuit with an off signal provided to the global enable input to determine a global clock capacitance for the micro gated clocking local clock buffer circuit;
performing a second simulation of the operation of the micro gated clocking local clock buffer circuit with an enable signal provided to the global enable input and off signals provided to each of the plurality of local clock enable inputs, wherein the enable signal alternates between an on and off signal, to determine a global enable capacitance parametrized on a duty cycle of the enable signal;
performing a third simulation of the operation of the micro gated clocking local clock buffer circuit with the enable signal provided to the global enable input and activation signals provided to each of the plurality of local clock enable inputs, wherein each of the activation signals alternates between an on and off signal with a corresponding activity level, to determine a local clock capacitance for each of the plurality of local clock enable inputs; and
calculating a power consumption of the micro gated clocking local clock buffer circuit based on the global clock capacitance, the global enable capacitance, and the local clock capacitance for each of the plurality of local clock enable inputs.

11. The system of claim 10, wherein the power consumption of the micro gated clocking local clock buffer circuit is calculated by multiplying a sum of the global clock capacitance, the global enable capacitance times the duty cycle, and the clock capacitance for each of the plurality of local clock enable inputs times the corresponding activity level by a square of a voltage level and frequency of a global clock signal.

12. The system of claim 10, wherein plurality of local clock enable inputs is at least two.

13. The system of claim 10, wherein the third simulation includes varying a state of each of the activation signals and recording the corresponding activity level.

14. The system of claim 13, wherein the corresponding activity level of each of the activation signals is a duty cycle of the activation signals.

15. The system of claim 10, wherein the model of the micro gated clocking local clock buffer circuit is independent of process, voltage, and temperature (PVT) variations in the micro gated clocking local clock buffer circuit.

16. The system of claim 10, wherein the micro gated clocking local clock buffer circuit comprises a plurality of local clock outputs, each corresponding to one of the plurality of local clock enable inputs.

17. The system of claim 10, wherein performing the first, second, and third simulations capture all operational states of the micro gated clocking local clock buffer circuit.

18. A computer program product for circuit design optimization, the computer program product comprising:
a set of one or more computer-readable storage media;
program instructions, collectively stored in the set of one or more storage media, for causing a processor set to perform the following computer operations:
obtaining a model of a micro gated clocking local clock buffer circuit, wherein the model includes a global enable input and a plurality of local clock enable inputs;
performing a first simulation of an operation of the micro gated clocking local clock buffer circuit with an off signal provided to the global enable input to determine a global clock capacitance for the micro gated clocking local clock buffer circuit;
performing a second simulation of the operation of the micro gated clocking local clock buffer circuit with an enable signal provided to the global enable input and off signals provided to each of the plurality of local clock enable inputs, wherein the enable signal alternates between an on and off signal, to determine a global enable capacitance parametrized on a duty cycle of the enable signal;
performing a third simulation of the operation of the micro gated clocking local clock buffer circuit with the enable signal provided to the global enable input and activation signals provided to each of the plurality of local clock enable inputs, wherein each of the activation signals alternates between an on and off signal with a corresponding activity level, to determine a local clock capacitance for each of the plurality of local clock enable inputs; and
calculating a power consumption of the micro gated clocking local clock buffer circuit based on the global clock capacitance, the global enable capacitance, and the local clock capacitance for each of the plurality of local clock enable inputs.

19. The computer program product of claim 18, wherein the power consumption of the micro gated clocking local clock buffer circuit is calculated by multiplying a sum of the global clock capacitance, the global enable capacitance times the duty cycle, and the clock capacitance for each of the plurality of local clock enable inputs times the corresponding activity level by a square of a voltage level and frequency of a global clock signal.

20. The computer program product of claim 18, wherein the third simulation includes varying a state of each of the activation signals and recording the corresponding activity level.
